(19) United States
(12) Patent Application Publication
(10) Pub. No.: US 2026/0271464 A1
(43) Pub. Date: Sep. 10, 2026

(54) DISPLAY DEVICE, METHOD OF MANUFACTURING THE SAME AND ELECTRONIC DEVICE INCLUDING THE SAME

(71) Applicant: SAMSUNG DISPLAY CO., LTD., YONGIN-SI (KR)

(72) Inventor: Kyu-Ho JUNG, Yongin-si (KR)

(21) Appl. No.: 19/558,867

(22) Filed: Mar. 6, 2026

(30) Foreign Application Priority Data
Mar. 7, 2025 (KR) 10-2025-0030026

(51) Int. Cl. H10H 29/853; H10H 29/01; H10H 29/855

(52) U.S. Cl. CPC H10H 29/853; H10H 29/0362; H10H 29/0363; H10H 29/8552

(57) ABSTRACT

A display device includes a display panel, and a capping stack on the display panel. The capping stack includes an adhesive layer attached on the display panel, a capping layer on the adhesive layer, a polarizing plate on the capping layer, and a shielding portion that covers both side surfaces of the adhesive layer and the capping layer in a first direction parallel to a top surface of the display panel and both side surfaces of the display panel in a second direction parallel to the top surface of the display panel and perpendicular to the first direction. The shielding portion does not cover a side surface of the display panel.

### CROSS-REFERENCE TO RELATED APPLICATION

This U.S. non-provisional patent application claims priority under 35 U.S.C. § 119 to Korean Patent Application No. 10-2025-0030026 filed on Mar. 7, 2025 in the Korean Intellectual Property Office (KIPO), the disclosure of which is incorporated by reference herein in its entirety.

### BACKGROUND

### 1. Field

Embodiments of the present disclosure relate to a display device, a method of manufacturing the same, and an electronic device including the same. More particularly, embodiments of the present disclosure relate to a display device including a display panel and a capping layer, a method of manufacturing the same, and an electronic device including the same.

### 2. Discussion of the Related Art

Display devices, such as an organic light emitting diode (OLED) display device and a liquid crystal display (LCD) device, typically include a display panel, which includes a display substrate. The display substrate may include, a thin film transistor (TFT) array, electrodes, and emission layers.

A protective layer may be formed on the display panel to protect the display panel from environmental factors. In some cases, a polarizing plate may be stacked on the display panel to prevent reflection of external light.

### SUMMARY

According to an aspect of the present disclosure, there is provided a display device having improved optical reliability and mechanical stability.

According to an aspect of the present disclosure, there is provided a method of manufacturing a display device having improved optical reliability and mechanical stability.

According to an aspect of the present disclosure, there is provided an electronic device including a display device with improved optical reliability and mechanical stability.

A display device according to embodiments may include a display panel, and a capping stack on the display panel. The capping stack may include an adhesive layer attached on the display panel, a capping layer on the adhesive layer, a polarizing plate on the capping layer, and a shielding portion that covers both side surfaces of the adhesive layer and the capping layer in a first direction parallel to a top surface of the display panel and both side surfaces of the adhesive layer and the capping layer in a second direction parallel to the top surface of the display panel and perpendicular to the first direction. The shielding portion may not cover a side surface of the display panel.

In some embodiments, the shielding portion may contact a bottom surface of the polarizing plate, and does not cover a side surface of the polarizing plate.

In some embodiments, the shielding portion may partially cover the side surfaces of the adhesive layer.

In some embodiments, the shielding portion may entirely cover the side surfaces of the capping layer.

In some embodiments, the shielding portion may be spaced apart in a thickness direction from the top surface of the display panel.

In some embodiments, the shielding portion may include a first shielding portion covering one side surfaces of the capping layer and the adhesive layer in the first direction, a second shielding portion covering the other side surfaces of the capping layer and the adhesive layer in the first direction, a third shielding portion covering one side surfaces of the capping layer and the adhesive layer in the second direction, and a fourth shielding portion covering the other side surfaces of the capping layer and the adhesive layer in the second direction. The display panel may include a pad adjacent to the other side surface of the adhesive layer in the second direction on the top surface of the display panel.

In some embodiments, wherein an outer surface of each of the first shielding portion, the second shielding portion, and the third shielding portion may have a bent shape.

In some embodiments, each of the first shielding portion, the second shielding portion and the third shielding portion may include a first portion adjacent to the polarizing plate and a second portion adjacent to the display panel. An inclination angle of the outer surface of the first portion with respect to the thickness direction may be smaller than an inclination angle of the outer surface of the second portion with respect to the thickness direction.

In some embodiments, the outer surface of the fourth shielding portion may have a straight inclined surface.

In some embodiments, the one side surfaces of the capping layer and the adhesive layer in the first direction may protrude from one side surface of the display panel in the first direction, and the other side surfaces of the capping layer and the adhesive layer in the first direction may protrude from the other side surface in the first direction of the display panel.

In some embodiments, the one side surfaces of the capping layer and the adhesive layer in the second direction may protrude from one side surface of the display panel in the second direction.

In some embodiments, the capping layer may include a transparent resin film having a Young's modulus in a range from 0.5 GPa to 1.5 GPa.

In some embodiments, a thickness of the capping layer may be greater than a thickness of the adhesive layer, and the thickness of the capping layer may be in a range from 80 μm to 200 μm, and the thickness of the adhesive layer may be in a range from 30 μm to 80 μm.

In a method for manufacturing a display device, a capping unit stack including a capping liner, a capping layer, and an adhesive layer which are sequentially stacked may be prepared. A shielding layer covering side surfaces of the capping layer and the adhesive layer may be formed on a margin area of the capping liner which is not covered by the capping layer. The capping unit stack including the shielding layer may be attached to a display panel by the adhesive layer. The capping liner may be removed. A polarizing plate may be stacked on surfaces of the shielding layer and the capping layer from which the capping liner is removed. Side portions of the polarizing plate and the shielding layer may be cut.

In some embodiments, the display panel may include a pad area, and cutting the side portions of the polarizing plate and the shielding layer may not be performed on a side portion on the display panel adjacent to the pad area.

In some embodiments, the capping unit stack may further include an adhesive liner stacked on the adhesive layer, and the shielding layer may not contact the adhesive liner.

In some embodiments, the shielding layer may be formed to partially cover a side surface of the adhesive layer.

In some embodiments, in attaching the capping unit stack to the display panel, the adhesive liner may be removed. The capping unit stack may be attached to a top surface of the display panel by a surface of the adhesive layer from which the adhesive liner is removed.

An electronic device according to some embodiments includes a display device, a memory, and a processor executing data included in the memory to control an operation of the display device. The display device may include a display panel, and a capping stack on the display panel. The capping stack may include an adhesive layer attached on the display panel, a capping layer on the adhesive layer, a polarizing plate on the capping layer, and a shielding portion that covers both side surfaces of the adhesive layer and the capping layer in a first direction parallel to a top surface of the display panel and both side surfaces of the adhesive layer and the capping layer in a second direction parallel to the top surface of the display panel and perpendicular to the first direction. The shielding portion may not cover a side surface of the display panel.

In some embodiments, the electronic device may include virtual reality or augmented reality glasses, a smartphone, a tablet personal computer, a laptop, a television, a desk monitor, smart glasses, a head-mounted display, a smart watch, or a vehicle display.

According to embodiments of the present disclosure, a capping stack including a four-sided shielding portion may be formed on a display panel to improve mechanical stability of a thin display device and sufficiently prevent light-leakage.

In some embodiments, contamination and damage of pad portions of the display panel may be prevented by adjusting a height and a gap with the display panel of the shielding portion. While preventing light-leakage.

### BRIEF DESCRIPTION OF THE DRAWINGS

FIGS. 1 and 2 are schematic cross-sectional views illustrating a display device according to an embodiment.

FIG. 3 is a schematic plan view illustrating a display panel of a display device according to an embodiment.

FIG. 4 is a schematic cross-sectional view illustrating a display panel of a display device according to an embodiment.

FIGS. 5 to 21 are schematic diagrams illustrating a method of manufacturing a display device according to some embodiments.

FIGS. 22 to 27 are schematic diagrams illustrating a method of manufacturing a display device according to a comparative example.

FIG. 28 is a block diagram of an electronic device according to an embodiment.

FIG. 29 is a schematic diagram of electronic devices according to an embodiment.

### DETAILED DESCRIPTION OF EMBODIMENTS

Hereinafter, embodiments of the present invention will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the present invention.

The terms “on”, “connected”, “coupled,” etc., used herein refers to a direct placement/connection/combination, and also refers to a case where another element is interposed two different elements.

The terms such as “first”, “second”, “below”, “under”, “above,” “on,” etc., are used in a relative sense to distinguish different elements or positions, and do not specify an absolute position or an absolute order.

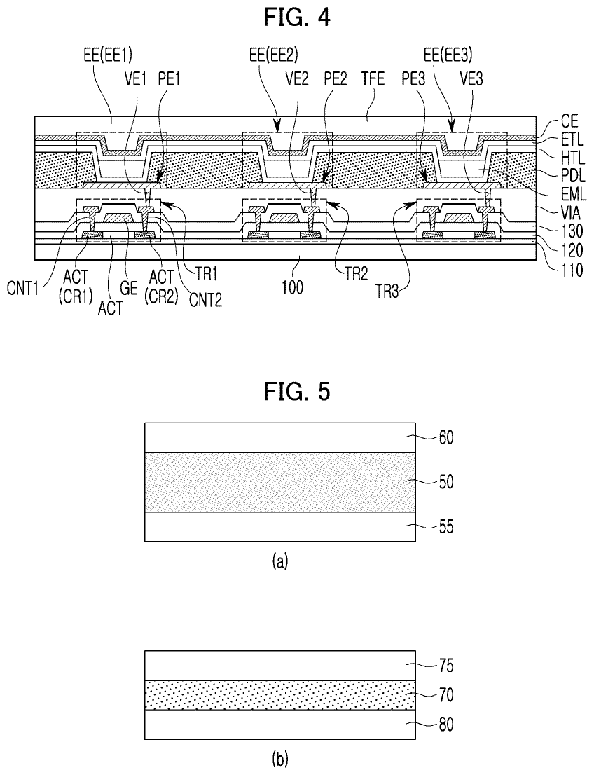

In the accompanying drawings, a first direction and a second direction may refer to two directions parallel to a display surface of a display panel DP or a base substrate 100 (see FIG. 4) and intersecting each other. For example, the first direction and the second direction may be perpendicular to each other.

For example, the first direction may correspond to an X-direction (e.g., a row direction or a width direction) of the display device, and the second direction may correspond to a Y-direction (a column direction or a length direction) of the display device. A third direction may be perpendicular to the first direction and the second direction. The third direction may correspond to a Z-direction (a thickness direction) of the display device.

Display devices, such as organic light emitting diode (OLED) displays and liquid crystal displays (LCDs), typically include a display panel and a protective layer to prevent damage and external interference. The display panel may include a thin film transistor (TFT) array, electrodes, and emission layers, and the protective layer may be formed on top of the display panel to protect it from environmental factors. In some cases, a polarizing plate may be stacked on the display panel to reduce reflection and improve visibility. However, these approaches may not provide sufficient protection against mechanical stress and light leakage, which can affect the overall performance and reliability of the display device.

According to embodiments of the present inventive concepts, a capping layer and a shielding portion may be used to protect the display panel and prevent light leakage. For example, a capping layer with a high modulus, in combination with a shielding portion, may provide mechanical stability and block or reduce the light leakage from the display panel. For example, according to one embodiment, a display panel may be provided with a capping stack on the display panel. The capping stack may comprise an adhesive layer attached on the display panel, the capping layer on the adhesive layer, a polarizing plate on the capping layer; and the shielding portion that covers side surfaces of the adhesive layer. The capping layer may be attached to a top surface of the display panel, and the shielding portion may not contact a side surface of the display panel.

In the accompanying drawings, the above definition of the directions may be equally applied.

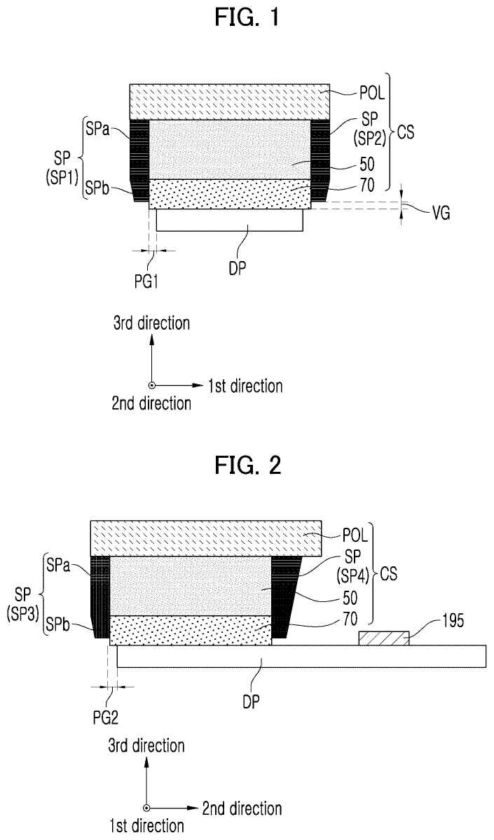

FIGS. 1 and 2 are schematic cross-sectional views illustrating a display device according to embodiments.

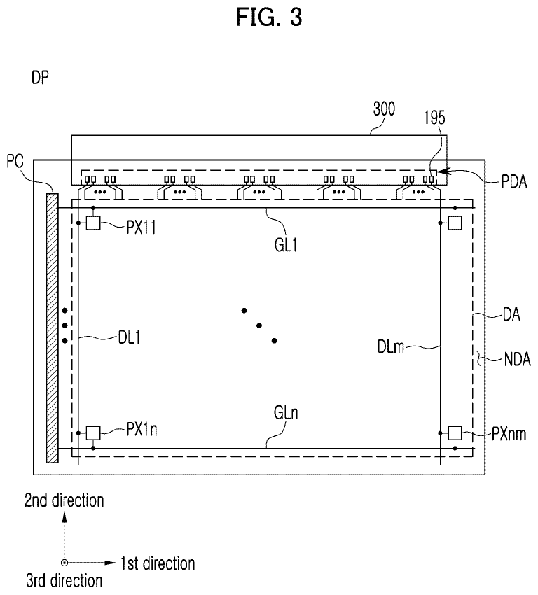

Referring to FIG. 1, a display device may include the display panel DP and a capping stack CS stacked on the display panel DP. Elements and structures of the display panel DP will be described later in more detail with reference to FIGS. 3 and 4.

The capping stack CS may include a sequential stack of an adhesive layer 70, a capping layer 50, and a polarizing plate POL, and may be attached to the display panel DP by the adhesive layer 70. The term “adhesive layer” used herein may encompass a pressure-sensitive adhesive layer and a bonding layer.

In some embodiments, the adhesive layer 70 may be formed using an adhesive such as an optically clear adhesive (OCA) or a pressure-sensitive adhesive (PSA) including an acrylic resin or a silicone resin.

The adhesive layer 70 may have a storage modulus in a range from 0.05 MPa to 0.1 MPa. In an embodiment, the adhesive layer 70 may have a storage modulus in a range from 0.06 MPa to 0.09 MPa, or from 0.07 MPa to 0.09 MPa. In the storage modulus range, impact absorption properties by the adhesive layer 70 may be improved while enhancing adhesion to the display panel DP.

The capping layer 50 may include a transparent resin film with a relatively high modulus. According to some embodiments, a Young's modulus of the capping layer 50 may be in a range from 0.5 GPa to 1.5 GPa. In some embodiments, the Young's modulus of the capping layer 50 may be in a range from 0.6 GPa to 1.4 GPa, or from 0.7 GPa to 1.2 GPa. In the Young's modulus range, flexibility and folding/bending properties of the display device may be appropriately maintained while sufficiently achieving mechanical rigidity and impact resistance of the capping layer 50.

For example, the capping layer 50 may include a polyester-based resin such as polyethylene terephthalate, polyethylene isophthalate, polyethylene naphthalate, polybutylene terephthalate, etc.; a cellulose-based resin such as diacetyl cellulose, triacetyl cellulose, etc.; a polycarbonate-based resin; an acrylic resin such as polymethyl (meth)acrylate, polyethyl (meth)acrylate, etc.; a styrene-based resin such as polystyrene, an acrylonitrile-styrene copolymer, etc.; a polyolefin-based resin such as polyethylene, polypropylene, a cycloolefin or polyolefin having a norbornene structure, an ethylene-propylene copolymer, etc.; a vinyl chloride-based resin; an amide-based resin such as nylon, an aromatic polyamide, etc.; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more therefrom.

In some embodiments, the capping layer 50 may include an acryl urethane-based resin. In this embodiment, the Young's modulus range of the capping layer 50 may be easily obtained.

A thickness of the capping layer 50 may be greater than a thickness of the adhesive layer 70. In some embodiments, the thickness of the capping layer 50 may be in a range from 80 μm to 200 μm, from 80 μm to 180 μm, or from 80 μm to 150 μm. The thickness of the adhesive layer 70 may be in a range from 30 μm to 80 μm, from 40 μm to 70 μm, or from 40 to 60 μm.

With the above thickness range, e.g., an ultra-thin display device may be stably implemented while maintaining adhesion stability and impact dispersive properties by the adhesive layer 70, and impact resistance by the capping layer 50.

The polarizing plate POL may include a polarizer. A protective film may be attached to a surface of the polarizer to provide a film-type polarizing plate POL.

The polarizer may include an iodine-stained polyvinyl alcohol (PVA) film. The polarizer may be stretched in a specific uniaxial direction to provide polarization properties as iodine molecules are oriented.

The protective film may include a first protective film attached to a bottom surface of the polarizer and a second protective film attached to a top surface of the polarizer.

The protective film may include a resin film having enhanced transparency, mechanical strength, thermal stability, moisture-shielding properties, isotropic properties, etc. For example, the protective film may include an acrylic resin film such as polymethyl(meth)acrylate, polyethyl(meth)acrylate, etc.; a polyester-based resin film such as polyethylene terephthalate, polyethylene isophthalate, polyethylene naphthalate, polybutylene terephthalate, etc.; a cellulose-based resin film such as diacetylcellulose, triacetylcellulose, etc.; a polyolefin-based resin film such as polyethylene, polypropylene, a cycloolefin or polyolefin having a norbornene structure, an ethylene-propylene copolymer, etc. In some embodiments, the protective film may include a cellulose-based resin film such as triacetylcellulose (TAC).

In some embodiments, the protective film may be attached to the polarizer by an adhesive layer. For example, the adhesive layer may be formed by coating a photocurable adhesive composition on an attachment surface of the polarizer or protective film, and cross-linking the adhesive composition through an exposure process. The photocurable adhesive composition may include an acrylate-based photopolymerizable compound, a photopolymerization initiator, and a solvent.

A thickness of the polarizing plate POL may be greater than a thickness of the capping layer 50. The polarizing plate POL may be provided as an outermost protective layer of the display device. Accordingly, sufficient external rigidity may be obtained while suppressing reflection of external light of the display device by the polarizing plate POL.

For example, the thickness of the polarizing plate POL may be in a range from 100 μm to 200 μm, from 120 μm to 180 μm, from 130 μm to 170 μm, or from 130 μm to 160 μm.

The capping stack CS may further include a shielding portion SP. According to some embodiments of the present inventive concepts, the shielding portion SP may be formed on four side portions of the capping stack CS.

The shielding portion SP may include a first shielding portion SP1 and a second shielding portion SP2 formed on both side portions of the capping stack CS in the first direction, respectively, of the display device, and a third shielding portion SP3 and a fourth shielding portion SP4 formed on both side portions of the capping stack CS, respectively, in the second direction of the display device.

The shielding portion SP may be formed as a colored resin pattern to block light-leakage generated from the display panel DP. According to some embodiments, the shielding portion SP may be formed as a black resin layer.

The first to fourth shielding portions SP1, SP2, SP3, and SP4 may be integrally connected to each other along a side periphery of the capping layer 50. Therefore, side light-leakage of the display device may be effectively blocked.

The shielding portion SP may be in contact with a bottom surface (a surface facing the display panel DP) of the polarizing plate POL. Accordingly, the shielding portion SP may cover a side surface of the capping layer 50 and the bottom surface of the polarizing plate POL, and may block light-leakage to a side surface and a front surface of the display device.

In some embodiments, the shielding portion SP may not contact a side surface of the polarizing plate POL.

In some embodiments, at least one of the first to fourth shielding portions SP1, SP2, SP3, and SP4 may include a first portion SPa and a second portion SPb having side surfaces of different inclination angles. The first portion SPa may correspond to an upper portion of the shielding portion SP adjacent to the polarizing plate POL, and the second portion SPb may correspond to a lower portion of the shielding portion SP adjacent to the display panel DP.

An outer surface of the second portion SPb may have a shape bent from an outer surface of the first portion SPa. An inclination angle of the outer surface of the first portion SPa with respect to the third direction (the thickness direction) may be smaller than an inclination angle of the outer surface of the second portion SPb with respect to the third direction.

In some embodiments, the first portion SPa may have a substantially vertical outer surface, and an inclination angle of the outer surface of the first portion SPa with respect to the third direction (thickness direction) may be substantially zero.

According to embodiments, the first shielding portion SP1, the second shielding portion SP2, and the third shielding portion SP3 may each include the first portion SPa and the second portion SPb as described above. As will be described later, the first portion SPa and the second portion SPb may be divided from each other by a cutting process such as a laser cutting process.

In some embodiments, the fourth shielding portion SP4 may have an outer surface of a substantially continuous straight line. The fourth shielding portion SP4 may be positioned on a side portion of the display panel DP in the second direction in which the pad 195 is included. The cutting process may be omitted from the fourth shielding portion SP4, thereby preventing circuit damages to a pad area in which the pad 195 is included.

Side portions of the adhesive layer 70 and the capping layer 50 of the capping stack CS in the first direction may protrude in the first direction from a side portion of the display panel DP in the first direction. As illustrated in FIG. 1, side surfaces of the adhesive layer 70 and the capping layer 50 in the first direction and a side surface of the display panel DP in the first direction may be spaced apart from each other by a distance corresponding to a first protruding gap PG1.

As illustrated in FIG. 2, one side portions of the adhesive layer 70 and the capping layer 50 of the capping stack CS in the second direction may protrude in the second direction from one side portion of the display panel DP in the second direction. One side surfaces of the adhesive layer 70 and the capping layer 50 in the second direction, and a side surface of the display panel DP in the second direction may be spaced apart from each other by a distance corresponding to a second protruding gap PG2.

According to some embodiments, the other side surfaces of the adhesive layer 70 and the capping layer 50 of the capping stack CS in the second direction may be positioned on a top surface of the display panel DP. The other side portion of the display panel DP including the pad area may protrude in the second direction from the other side surfaces of the adhesive layer and the capping layer 50 of the capping stack CS in the second direction.

As described above, both side portions of the display panel DP in the first direction and one side portion in the second direction may be completely covered by the adhesive layer 70 and the capping layer 50 of the capping stack CS, so that mechanical stability of the display device may be achieved, and side light-leakage may be sufficiently blocked. The other side portion of the display panel DP in the second direction may include a portion that does not overlap the capping stack CS, thereby improving electrical stability of the pad 195 and bonding stability with a circuit board.

According to some embodiments, the shielding portion SP may not be in contact with side surfaces of the display panel DP. Accordingly, when the capping stack CS is misaligned, and then detached from the display panel DP, optical defects caused by a remaining shielding portion SP on the display panel DP may be prevented.

According to some embodiments, the shielding portion SP may cover the entire side surface of the capping layer 50, and may partially cover the side surface of the adhesive layer 70. Accordingly, as illustrated in FIG. 1, a bottom surface (a surface adjacent to the display panel DP) of the adhesive layer 70 and a bottom surface of the shielding portion SP may be spaced apart from each other by a distance corresponding to a vertical gap VG in the third direction (the thickness direction).

Thus, the fourth shielding portion SP may be spaced apart from the top surface of the display panel DP. For example, the fourth shielding portion SP may be spaced apart from the top surface of the display panel DP by a distance corresponding to the vertical gap VG. The shielding portion SP may be spaced apart from the top surface of the display panel, and the pad area may be unshielded by the shielding portion SP, so that improved electrical reliability can be realized. Further, contamination and damage of pad portions of the display panel may be prevented, electrical and bonding stability of the pad and a circuit board may be improved, and more reliable and efficient data transfer between the display device and other components may be implemented.

FIG. 3 is a schematic plan view illustrating a display panel of a display device according to some embodiments. FIG. 4 is a schematic cross-sectional view illustrating a display panel of a display device according to some embodiments.

Referring to FIG. 3, the display panel DP may include a display area DA and a non-display area NDA. The display area DA may provide a surface on which an image of the display device is substantially displayed and a user's touch/command is input. The non-display area NDA may substantially correspond to a bezel area or a peripheral area of the display device. In an embodiment, the display area DA may be substantially surrounded by the non-display area NDA.

According to some embodiments, the display area DA may be substantially completely covered by the capping stack CS. In some embodiments, the display area DA may be substantially completely covered by the capping layer 50 and the adhesive layer 70 of the capping stack CS.

The side portions of the display panel DP in the first direction and a portion of the non-display area NDA included in one side portion in the second direction may be substantially completely covered by the capping stack CS (the capping layer 50 and the adhesive layer 70).

As described above, a pad area PDA in which the pads 195 are arranged may be included in the other side portion of the non-display area NDA in the second direction. According to some embodiments, the capping layer 50 and the adhesive layer 70 of the capping stack CS may not cover the pad area PDA. In some embodiments, the fourth shielding portion SP4 may not cover the pad area PDA in a plan view.

The base substrate 100 may also be divided into the display area DA and the non-display area NDA. A plurality of pixels PX11 to PXnm may be arranged on the display area DA of the base substrate 100.

In example embodiments, a pixel circuit including scan lines SL1 to SLn (or gate lines) forming first to n^{th} rows, and data lines DL1 to DLm forming first to m^{th} columns may be arranged on a base substrate 100 of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel circuit including a transistor, and a light-emitting element as described below. Although not illustrated in detail in FIG. 3, the pixel circuit may further include wirings such as a power line, a ground line, etc.

FIG. 3 illustrates that the data lines DL1 to DLm extend in the second direction DR2 and the scan lines SL1 to SLn extend in the first direction DR1, but the construction of the data lines and the gate lines is not limited to that illustrated in FIG. 3. In FIG. 3, the shape of each pixel PX11 to PXnm is illustrated as a square shape for convenience of illustration, but the shape of each pixel is not limited thereto.

A peripheral circuit PC may be disposed in the non-display area NDA corresponding to a peripheral area of the display area DA. For example, the peripheral circuit PC may include a gate driving circuit. The gate driving circuit may be integrated into the display panel DP by an oxide semiconductor gate (OSG) driver circuit process, an amorphous silicon gate (ASG) driver circuit process, or a polysilicon gate (PSG) driver circuit process.

The peripheral circuit PC may further include a data driver, a gate driver, a light-emitting driver, a power voltage generator, a timing controller, or the like.

The display device may further include a printed circuit board 300. The pads 195 of the pixel circuit may be assembled at the side portion of the non-display area NDA in the second direction. The printed circuit board 300 may be electrically connected to the pixel circuit through the pads 195. For example, the printed circuit board 300 may be electrically connected to the pads 195 by a heat-compression process using a conductive intermediate structure such as an anisotropic conductive film (ACF).

An integrated circuit (IC) such as a data driving circuit may be disposed on the printed circuit board 300. In some embodiments, an integrated circuit (IC) chip in the form of a chip-on-film (COF) may be mounted on the printed circuit board 300.

Referring to FIG. 4, the display panel DP may include the base substrate 100, the pixel circuit including transistor structures TR1, TR2, and TR3, and the light-emitting element EE.

The base substrate 100 may serve as a back-plane substrate of a display device. A glass substrate, a ceramic substrate, or a plastic substrate may be used as the base substrate 100. In some embodiments, the base substrate 100 may include a polymer material having transparency and flexibility. In this case, the base substrate 100 may be used in a transparent flexible display device.

For example, the base substrate 100 may include a polymer material such as polyimide, polysiloxane, an epoxy resin, an acrylic resin, polyester, or the like. In an embodiment, the base substrate 100 may include polyimide.

In an embodiment, the base substrate 100 may be a glass substrate. In an embodiment, the base substrate 100 may be a silicon substrate manufactured from a silicon wafer.

A buffer layer 110 may be formed on a top surface of the base substrate 100. Moisture penetrating through the base substrate 100 may be blocked by the buffer layer 110, and diffusion of impurities between the base substrate 100 and structures formed on the base substrate 100 may also be blocked by the buffer layer 110. The buffer layer 110 may be formed entirely over the display area DA and the non-display area NDA of the base substrate 100, and may entirely cover the top surface of the base substrate 100.

The buffer layer 110 may include, e.g., an inorganic insulating material such as silicon oxide, silicon nitride, silicon oxynitride, or the like. These may be used alone or in combination thereof.

In some embodiments, the buffer layer 110 may have a stacked structure including a silicon oxide layer and a silicon nitride layer. The buffer layer 110 may be formed by a deposition process such as a chemical vapor deposition (CVD) process, a sputtering process, an atomic layer deposition (ALD) process, or the like, to include the above-mentioned inorganic insulating material.

In some embodiments, the buffer layer 110 may include an organic layer, and may have a multi-layered structure of an organic layer and an inorganic layer.

The pixel circuit may include wirings including the scan lines and the data lines described with reference to FIG. 3, and the transistor structures TR1, TR2, and TR3 electrically interacting with the wirings. The transistor structures TR1, TR2, and TR3 may be electrically connected to the light-emitting elements EE1, EE2 and EE3, respectively.

Each of the transistor structures TR1, TR2 and TR3 may include an active layer ACT, a gate insulation layer 120, and a gate electrode GE. The transistor structures TR1, TR2, and TR3 may further include contact electrodes CNT1 and CNT2.

The active layer ACT may be disposed on the buffer layer 110, and may be patterned through a photo-lithography process to be repeatedly/regularly arranged at each pixel. The active layer ACT may include a silicon compound such as polysilicon or amorphous silicon. A p-type dopant or an n-type dopant may be doped in a partial region of the active layer ACT, and the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on an active layer ACT, and the gate electrode GE may be stacked on the gate insulation layer 120. As illustrated in FIG. 4, the gate insulation layer 120 may be included commonly throughout the first to third transistor structures TR1, TR2, and TR3, or a plurality of pixels of different colors.

In an embodiment, the gate insulation layer 120 may partially cover each buffer layer 110, and may be formed in a pattern shape independently at each of the first to third transistor structures TR1, TR2, and TR3.

The gate electrode GE may overlap the channel region of the active layer ACT in the third direction. A scan signal may be transmitted from the scan line through the gate electrode GE.

The gate insulation layer 120 may be formed by the above-mentioned deposition process to include an inorganic insulating material such as silicon oxide, silicon nitride, silicon oxynitride, a metal oxide, or the like.

In some embodiments, a p-type dopant or an n-type dopant may be injected into the active layer ACT by an ion implantation process using the gate electrode GE as an ion implantation mask. Accordingly, a first contact region CR1 and a second contact region CR2 may be formed on one side portion and the other side portion of the active layer ACT, respectively. The first contact region CR1 and the second contact region CR2 may correspond to a source region and a drain region, respectively.

A portion of the active layer ACT overlapping the gate electrode GE in a vertical direction (the third direction) and disposed between the first contact region CR1 and the second contact region CR2 may be defined as the channel region.

In some embodiments, the gate insulation layer 120 may be formed in a pattern covering the channel region through an etching process using the gate electrode GE as an etching mask. When the active layer ACT includes the oxide semiconductor, hydrogen (H) included in an insulating interlayer 130 may be diffused or transferred to the active layer ACT during the formation of the insulating interlayer 130. Accordingly, a carrier concentration may be increased by hydrogen to form the contact regions CR1 and CR2 at the side portions of the active layer ACT.

The insulating interlayer 130 covering the gate electrode GE and the gate insulation layer 120 may be formed on the active layer ACT. The insulating interlayer 130 may be formed by the above-mentioned deposition process to include an inorganic insulating material such as silicon oxide, silicon nitride, silicon oxynitride, or the like. The insulating interlayer 130 may be formed in a single-layered structure or a multi-layered structure including different materials.

The contact electrodes CNT1 and CNT2, which may be in contact with or electrically connected to the active layer ACT, may be formed on the insulating interlayer 130.

The contact electrode may include a first contact electrode CNT1 that may be connected to or in contact with the first contact region CR1 of the active layer ACT, and a second contact electrode CNT2 that may be connected to or in contact with the second contact region CR2 of the active layer ACT. In some embodiments, the first contact electrode CNT1 and the second contact electrode CNT2 may serve as a source electrode and a drain electrode, respectively.

According to some embodiments, the insulating interlayer 130 may be partially etched to form contact holes. For example, the contact holes exposing each of the first contact region CR1 and the second contact region CR2 may be formed. The contact holes may also extend through the gate insulation layer 120.

A metal layer may be formed on the insulating interlayer 130, and then may be partially etched to form the first contact electrode CNT1 and the second contact electrode CNT2. For example, a data signal may be transferred from the data line through the first contact electrode CNT1.

The gate electrode GE and the contact electrodes CNT1 and CNT2 may include a metal such as Ag, Mg, Al, W, Cu, Ni, Cr, Mo, Ti, Pt, Ta, Nd, Sc, an alloy thereof, or a nitride thereof. The gate electrode GE and the contact electrodes CNT1 and CNT2 may be formed by a deposition process, such as a sputtering process.

The gate electrode GE and the contact electrodes CNT1 and CNT2 may be formed in a multi-layered structure (e.g., a Ti layer-an Al layer-a Ti layer).

As described above, the first to third transistor structures TR1, TR2, and TR3 may be formed to form a thin film transistor TFT-array. The first transistor structure TR1, the second transistor structure TR2, and the third transistor structure TR3 may be transistor structures included in pixels of different colors.

A via insulation layer VIA, covering the contact electrodes CNT1 and CNT2, may be formed on the insulating interlayer 130. The via insulation layer VIA may be substantially provided as a planarization layer of the TFT-array.

The via insulation layer VIA may be partially etched to form a via hole exposing a top surface of the contact electrode (e.g., the second contact electrode CNT2), and then a via electrode filling the via hole may be formed. The via electrode may include a first via electrode VE1, a second via electrode VE2, and a third via electrode VE3 connected to the second contact electrode CNT2 of the first transistor structure TR1, the second transistor structure TR2, and the third transistor structure TR3, respectively.

In some embodiments, the via insulation layer VIA may be formed as an organic insulation layer. For example, the via insulation layer VIA may include an organic polymer material, such as polyimide, an epoxy resin, an acrylic resin, polyester, a siloxane resin, benzocyclobutene (BCB), or the like. For example, the via insulation layer VIA may be formed by a coating process, such as a spin coating process.

In an embodiment, the via insulation layer VIA may be formed of an inorganic insulating material, such as silicon oxide, silicon nitride, or silicon oxynitride. For example, the via insulation layer VIA may be formed through a deposition process, such as a CVD process.

The via electrodes VE1, VE2 and VE3 may be formed by a deposition process such as a sputtering process to include a metal such as Ag, Mg, Al, W, Cu, Ni, Cr, Mo, Ti, Pt, Ta, Nd, Sc, an alloy thereof, or a nitride thereof.

The first to third pixel electrodes PE1, PE2 and PE3 may be in contact with or electrically connected to the first to third via electrodes VE1, VE2 and VE3 on the via insulation layer VIA, respectively. Accordingly, the first to third pixel electrodes PE1, PE2 and PE3 may be electrically connected to a contact electrode (e.g., a second contact electrode CNT2) of the first to third transistor structures TR1, TR2 and TR3, respectively, through the first to third via electrodes VE1, VE2 and VE3.

The first light-emitting element EE1, the second light-emitting element EE2 and the third light-emitting element EE3 may be disposed on the via insulation layer VIA, and may be electrically connected to the first transistor structure TR1, the second transistor structure TR2 and the third transistor structure TR3, respectively. The first light-emitting element EE1, the second light-emitting element EE2, and the third light-emitting element EE3 may include the first pixel electrode PE1, the second pixel electrode PE2, and a third pixel electrode PE3, respectively, and may further include a light-emitting portion including an emission layer EML, and a counter electrode CE.

Each of the first to third pixel electrodes PE1, PE2 and PE3 may serve as an anode of the light-emitting element EE of the corresponding pixel. The pixel electrodes PE1, PE2 and PE3 may include a conductive material having a high work function to promote hole injection. The pixel electrodes PE1, PE2 and PE3 may be formed as transmissive electrode. The pixel electrodes PE1, PE2 and PE3 may include a transparent conductive oxide such as indium tin oxide (ITO), indium zinc oxide (IZO), zinc oxide (ZnO), indium zinc tin oxide (ITZO), or the like.

The pixel electrodes PE1, PE2 and PE3 may be formed as a translucent electrode or a reflective electrode. The pixel electrodes PE1, PE2 and PE3 may include a metal selected from Ag, Mg, Cu, Al, Pt, Pd, Au, Ni, Nd, Ir, Cr, Li, Ca, Mo, Ti, W, In, Sn or Zn, or an alloy or compound (e.g., LiF) containing at least one thereof.

The pixel electrodes PE1, PE2 and PE3 may have a single-layered structure or a multi-layered structure. For example, The pixel electrodes PE1, PE2 and PE3 may have a triple-layered structure of ITO/Ag/ITO or ITO/Al/ITO.

The pixel defining layer PDL may be formed on the via insulation layer VIA, and may include openings overlapping top surfaces of the pixel electrodes PE1, PE2 and PE3. A pixel region or a light-emitting region may be defined by the openings. For example, a blue light-emitting region, a green light-emitting region and a red light-emitting region may be separated/defined by the openings of the pixel defining layer PDL, and the first light-emitting element EE1, the second light-emitting element EE2 and the third light-emitting element EE3 may correspond to a blue light-emitting element, a green light-emitting element and a red light-emitting element, respectively.

In some embodiments, all of the light-emitting elements EE1, EE2 and EE3 may be white light-emitting elements or blue light emitting elements.

For example, the light-emitting portion may be formed by a process such as a thermal deposition, a vapor deposition, a vacuum deposition, a spin coating, an inkjet printing, a laser printing, a casting, a laser thermal transfer, or the like.

The counter electrode CE may be disposed on a top surface of the pixel defining layer PDL and the light-emitting portion. The counter electrode CE may be a common electrode continuously provided in a plurality of the light-emitting regions or the pixel regions.

The counter electrode CE may be provided as an electron injection electrode or a cathode. The counter electrode CE may include a metal, an alloy, an electrically conductive compound, or the like, having a low work function.

For example, the counter electrode CE may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in a combination of two or more therefrom.

The counter electrode CE may be formed as a transmissive electrode, a translucent electrode, or a reflective electrode. The counter electrode CE may have a single-layered structure or a multi-layered structure.

The light emitting portion may further include a hole transport layer HTL and an electron transport layer ETL. According to some embodiments, the hole transport layer HTL, the emission layer EML, the electron transport layer ETL and the counter electrode CE may be sequentially stacked from the top surfaces of the pixel electrodes PE1, PE2 and PE3.

For example, the hole transport layer HTL may include a hole transporting material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-l-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as Alq₃ (tris(8-hydroxyquinolinato)aluminum), TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the pixel electrodes PE1, PE2 and PE3, and the hole transport layer HTL. An electron injection layer may be further disposed between the counter electrode CE and the electron transport layer ETL.

In some embodiments, the layers included in the above-described light-emitting portion may be patterned within the light-emitting region defined by the pixel defining layer PDL together with the emission layer EML illustrated in FIG. 4. Accordingly, the light-emitting portions may be separated from each other in the form of islands spaced apart from each other in each light-emitting region.

In some embodiments, the layers included in the above-described light-emitting portion (e.g., the hole transport layer HTL and the electron transport layer ETL) may continuously and commonly extend across multiple light-emitting regions and the top surfaces of the pixel defining layer PDL.

The display panel DP may further include an encapsulation layer TFE covering the light-emitting elements EE1, EE2 and EE3.

The encapsulation layer TFE may include an inorganic layer including silicon nitride (SiNx), silicon oxide (SiOx), indium tin oxide, indium zinc oxide, or any combination thereof; or an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer and a second inorganic layer.

The capping stack CS described with reference to FIGS. 1 and 2 may be attached onto a top surface of the encapsulation layer TFE. In some embodiments, the display panel DP may further include a touch sensor layer stacked on the encapsulation layer TFE. In this case, the capping stack CS may be attached onto the touch sensor layer.

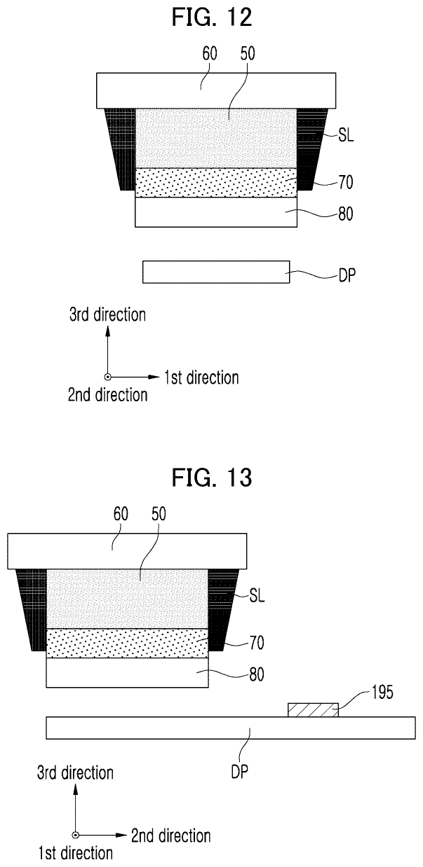

FIGS. 5 to 21 are schematic views illustrating a method of manufacturing a display device according to some embodiments. Specifically, FIGS. 5, 6, and 8 to 11 are schematic cross-sectional views illustrating a method of manufacturing a capping unit stack. FIG. 7 is a plan view of a capping mother film. FIGS. 12, 14, 16, 18, and 20 are cross-sectional views illustrating a capping unit stack or a capping stack, and a display panel taken along the first direction and the third direction. FIGS. 13, 15, 17, 19, and 21 are cross-sectional views illustrating a capping unit stack or a capping stack, and a display panel taken along the second direction and the third direction.

Referring to FIG. 5, a capping layer supply film (a mother film) ((a) of FIG. 5) including the capping layer 50 and an adhesive layer supply film (a mother film) ((b) of FIG. 5) including the adhesive layer 70 may be prepared.

The capping layer supply film may include a capping temporary protective film 55 attached to one surface of the capping layer 50, and a capping liner 60 attached to the other surface of the capping layer 50. The adhesive layer supply film may include an adhesive temporary protective film 75 attached to one surface of the adhesive layer 70 and an adhesive liner 80 attached to the other surface of the adhesive layer 70.

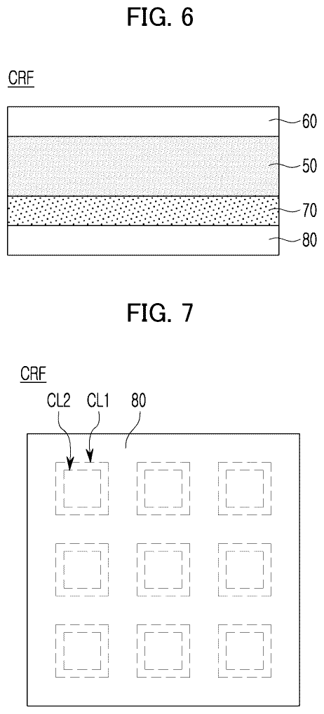

Referring to FIG. 6, the capping temporary protective film 55 may be removed from the capping layer supply film, and the adhesive temporary protective film 75 may be removed from the adhesive layer supply film. Thereafter, the adhesive layer 70 may be attached to one surface of the capping layer 50 to obtain a capping mother film CRF.

The combination of the capping layer supply film and the adhesive layer supply film may be performed through a roll-to-roll lamination process.

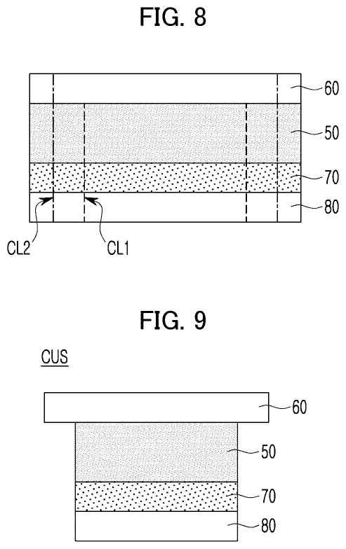

Referring to FIGS. 7 and 8, cutting lines CL1 and CL2 for cutting the capping mother film CRF may be set. The cutting lines CL1 and CL2 may include a first cutting line CL1 and a second cutting line CL2.

The first cutting line CL1 may be a partial cutting line of the capping mother film CRF. According to some embodiments, the first cutting line CL1 may be a cutting line of the adhesive liner 80, the adhesive layer 70, and the capping layer 50, and the capping liner 60 may not be substantially cut by the first cutting line CL1.

The second cutting line CL2 may be a full cutting line of the capping mother film CRF. The adhesive liner 80, the adhesive layer 70, the capping layer 50, and the capping liner 60 may be completely cut by the second cutting line CL2.

According to some embodiments, the second cutting line CL2 may be a full cutting line for cutting the capping mother film CRF in a cell unit or a display panel unit. The first cutting line CL1 may be a partial cutting line formed within the second cutting line CL2 to remain a margin area for forming a shielding layer on the capping liner 60.

Referring to FIG. 9, the capping mother film CRF may be cut by the first cutting line CL1 and the second cutting line CL2 to form a capping unit stack CUS having a size corresponding to the individual display panel DP.

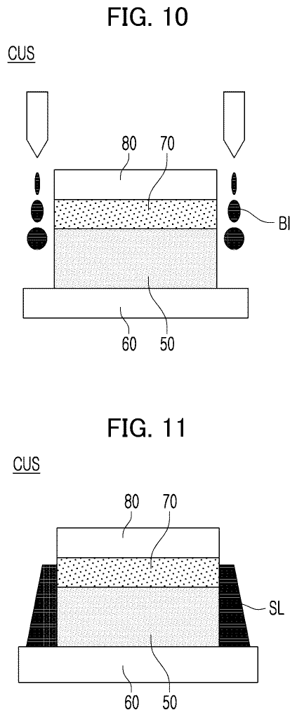

Referring to FIGS. 10 and 11, a shielding layer SL may be formed on the margin area of the capping liner 60 formed by partial cutting by the first cutting line CL1.

As illustrated in FIG. 10, a colored ink composition BI (e.g., a black ink composition) may be supplied on the margin area by, e.g., an inkjet process.

As illustrated in FIG. 11, the colored ink composition may be cured to form the shielding layer SL on a surface of the capping liner 60 in the margin area and four side surfaces of the capping layer 50 and the adhesive layer 70.

In some embodiments, the shielding layer SL may partially cover a side surface of the adhesive layer 70. In an embodiment, the shielding layer SL may be spaced apart from a top surface of the adhesive layer 70 (a surface opposite to an attachment surface with the capping layer 50) by a distance corresponding to a vertical gap VG shown in FIG. 1. Thus, the shielding layer SL may partially leave uncovered a side surface of the adhesive layer by the distance corresponding to the vertical gap VG shown in FIG. 1.

In some embodiments, an outer surface of the shielding layer SL may have an inclined surface shape with respect to the third direction (the thickness direction) from the capping liner 60.

Referring to FIGS. 12 and 13, the capping unit stack CUS including the shielding layer SL may be aligned on the display panel DP such that the adhesive liner 80 may face the display panel DP.

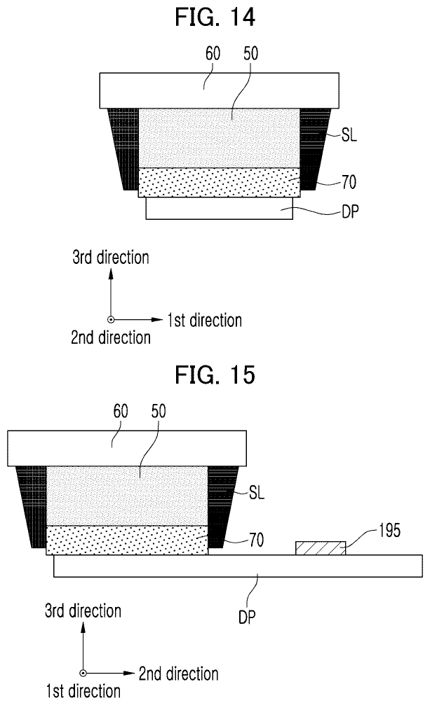

Referring to FIGS. 14 and 15, the adhesive liner 80 may be removed from the capping unit stack CUS, and then the capping unit stack CUS may be attached onto the display panel DP (e.g., on the encapsulation layer TFE).

As described above, the shielding layer SL may partially cover the side surface of the adhesive layer 70. Thus, when the adhesive liner 80 is removed, detachment and damage of the shielding layer SL may be prevented.

In some embodiments, a portion of the shielding layer SL adjacent to the pad 195 or the pad area PDA of the display panel DP may be spaced apart from the top surface of the display panel DP by a distance corresponding to the vertical gap VG (see FIG. 1).

In some embodiments, the shielding layer SL may also be disposed on all sides of the display panel DP to prevent light-leakage throughout entire side surfaces of the display device. In these embodiments, damages to the pad 195 by the shielding layer SL on the pad area PDA may be prevented, and a bonding process of the printed circuit board 300 (see FIG. 3) may be easily implemented without interference from the shielding layer SL.

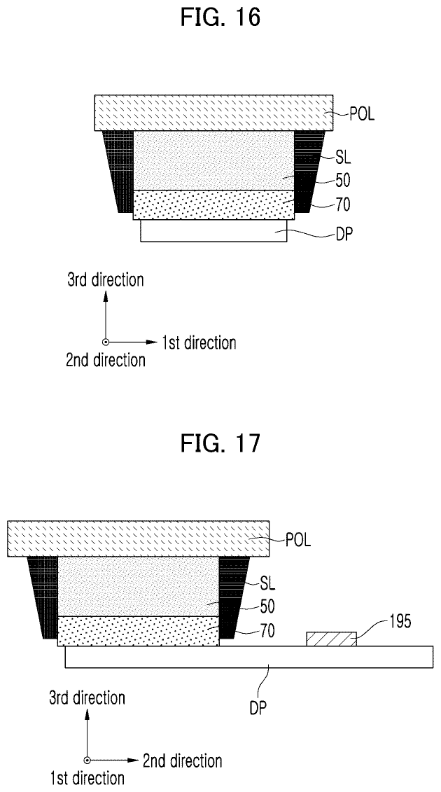

Referring to FIGS. 16 and 17, the capping liner 60 may be removed, and then the polarizing plate POL may be attached to top surfaces of the capping layer 50 and the shielding layer SL.

Accordingly, the capping stack including the adhesive layer 70, the capping layer 50, the polarizing plate POL, and the shielding layer SL may be combined with the display panel DP.

In some embodiments, an area of the polarizing plate POL may be greater than a sum of areas of top surfaces of the capping layer 50 and the shielding layer SL. Accordingly, the polarizing plate POL may include side portions protruding from the shielding layer SL in the first direction and the second direction.

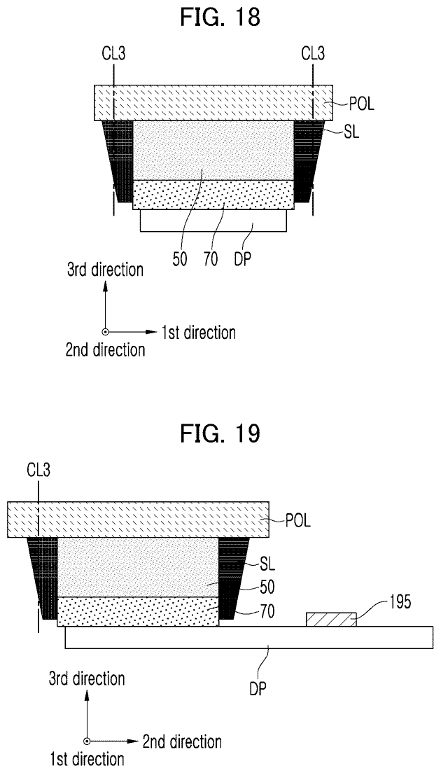

Referring to FIGS. 18 and 19, a third cutting line CL3 for cutting side portions of the polarizing plate POL and the shielding layer SL may be set.

According to some embodiments, the third cutting line CL3 may be set on one side portions and the other side portions of the polarizing plate POL and the shielding layer SL in the first direction, and may be set on one side portions in the second direction. In some embodiments, the third cutting line CL3 may not be set on the other side portions of the polarizing plate POL and the shielding layer SL in the second direction adjacent to the pad 195.

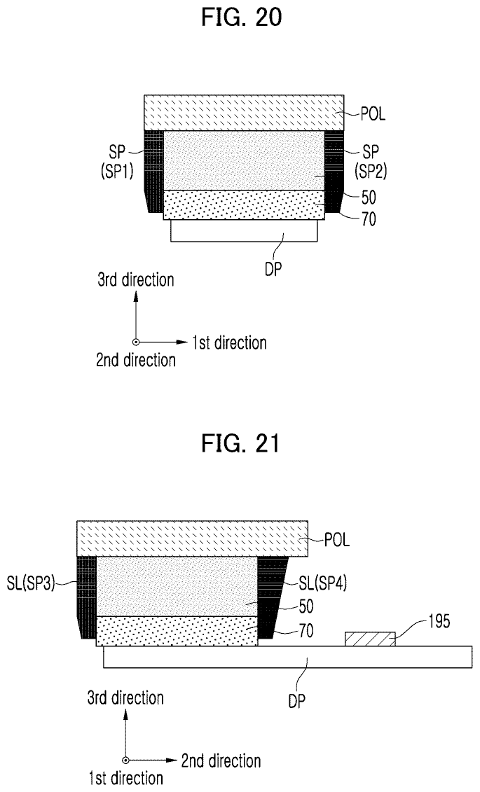

Referring to FIGS. 20 and 21, side portions of the polarizing plate POL and the shielding layer SL may be cut along the third cutting line CL3. Accordingly, the shielding portion SP may be formed by a remaining portion of the shielding layer SL.

The shielding portion SP may include the first shielding portion SP1 formed on one side surfaces of the capping layer 50 and the adhesive layer 70 in the first direction, the second shielding portion SP2 formed on the other side surfaces of the capping layer 50 and the adhesive layer 70 in the first direction, the third shielding portion SP3 formed on one side surfaces of the capping layer 50 and the adhesive layer 70 in the second direction, and the fourth shielding portion SP4 formed on the other side surfaces of the capping layer 50 and the adhesive layer 70 in the second direction.

As described with reference to FIGS. 1 and 2, the first to third shielding portions SP1, SP2, and SP3 may include the first portion SPa and the second portion SPb having outer surfaces with different inclination angles by a cutting process through the third cutting line CL3.

The cutting process may include use of a laser. As described above, in some embodiments, the cutting process may be omitted at the side portion including the pad 195 to prevent damage to the pad 195. Accordingly, the fourth shielding portion SP4 may include an outer surface having a substantially continuous straight line shape.

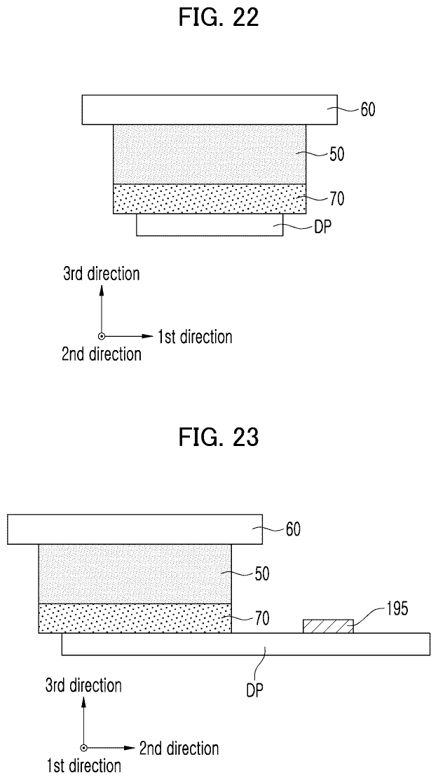

FIGS. 22 to 27 are schematic views illustrating a method of manufacturing a display device according to a comparative example. Specifically, FIGS. 22, 24 and 26 are cross-sectional views illustrating a display panel and a stacked structure on the display panel taken along the first direction and the third direction. FIGS. 23, 25 and 27 are cross-sectional views illustrating a display panel and a stacked structure on the display panel taken along the second direction and the third direction.

Referring to FIGS. 22 and 23, a capping unit stack including the adhesive layer 70, the capping layer 50, and the capping liner 60 may be attached onto the display panel DP.

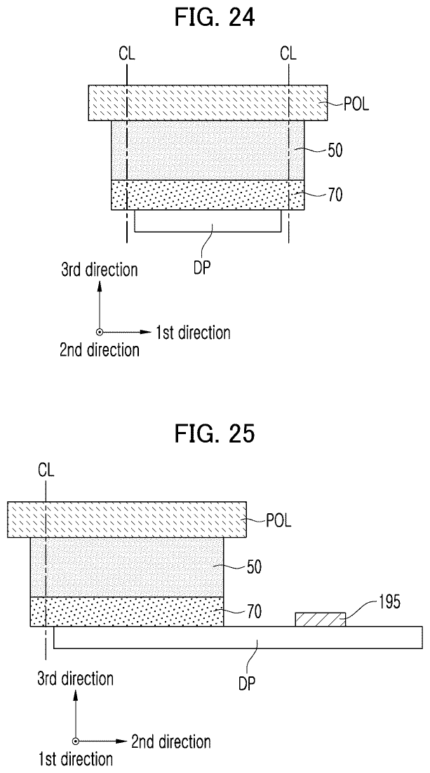

Referring to FIGS. 24 and 25, the capping liner 60 may be removed, and then the polarizing plate POL may be coupled to the capping layer 50. Thereafter, both side portions in the first direction and one side portion in the second direction of the polarizing plate POL, the capping layer 50 and the adhesive layer 70 may be cut along a cutting line CL.

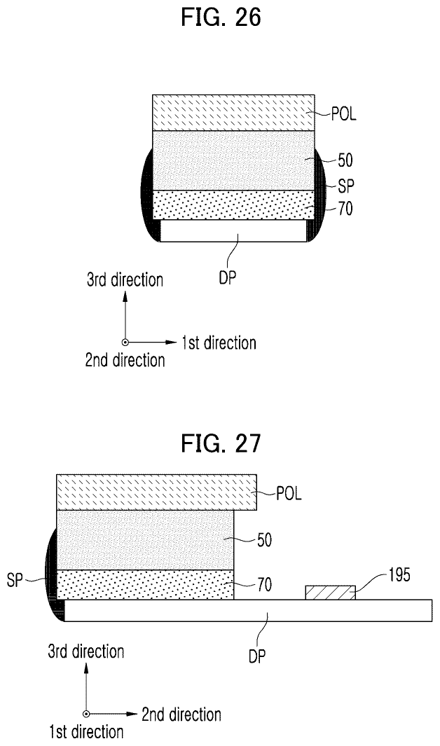

Referring to FIGS. 26 and 27, a shielding portion SP may be formed by applying a colored ink composition on both side surfaces in the first direction and one side surface in the second direction of the capping layer 50, the adhesive layer 70 and the display panel DP.

As illustrated in FIG. 27, the shielding portion SP is not formed on the other side portion of the display panel DP in the second direction in which the pad 195 is formed to prevent damage and contamination of the pad 195.

According to the above-described comparative example, the stacked structure including the capping layer 50 and the polarizing plate POL is attached onto the display panel DP, and then the shielding portion SP is formed on the sides of the stacked structure except for the side adjacent to the pad 195. Accordingly, the shielding portion SP is omitted from the side surface of the stacked structure adjacent to the pad area including the pad 195, and sufficient light-leakage suppression may not be implemented.

Further, a shape of an outer surface of the shielding portion SP may not be uniformly adjusted on each side surface.

However, according to some embodiments of the present disclosure as described above, the capping unit stack CUS including the shielding layer SL may be formed, and then the capping unit stack CUS may be attached to the display panel. Thus, the shielding portion SP may be maintained on the side surface of the capping unit stack CUS or the capping stack CS adjacent to the pad area.

Additionally, the shielding portion SP may be cut together with the cutting process of the polarizing plate POL. Accordingly, the shape of the outer surface of the shielding portion SP (e.g., the first to third shielding portions SP1, SP2 and SP3) may be uniformly controlled.

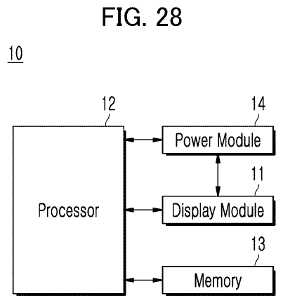

FIG. 28 is a block diagram of an electronic device in accordance with an embodiment.

Referring to FIG. 28, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal, and output image information through a display screen.

The power module 14 may include a power supply module such as a power adapter or a battery device, and a power conversion module that converts power supplied by the power supply module to generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

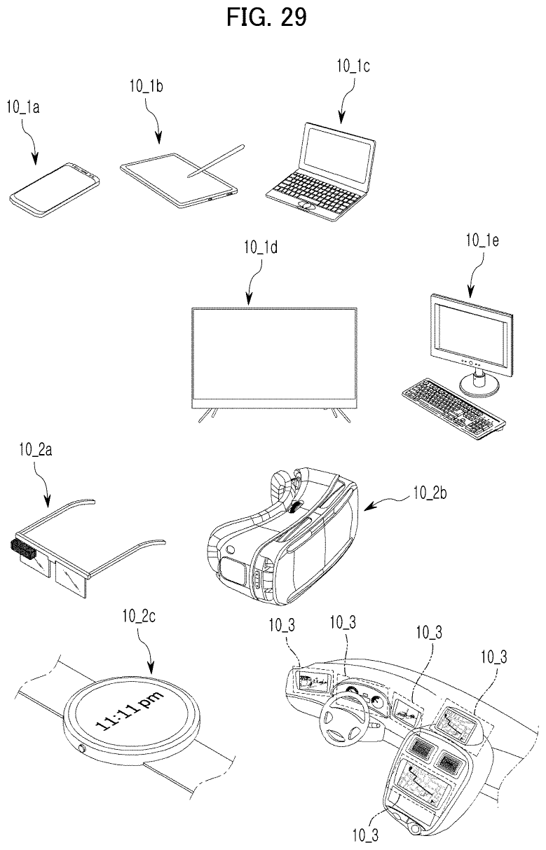

FIG. 29 is a schematic diagram of electronic devices in accordance with various embodiments.

Referring to FIG. 29, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, a head-up display, or the like. The electronic device may include a virtual reality glass or an augmented reality glass.

What is claimed is:

1. A display device, comprising:
a display panel; and
a capping stack on the display panel, the capping stack comprising:
an adhesive layer attached to the display panel,
a capping layer on the adhesive layer;
a polarizing plate on the capping layer; and
a shielding portion that covers both side surfaces of the adhesive layer and the capping layer in a first direction parallel to a top surface of the display panel and both side surfaces of the adhesive layer and the capping layer in a second direction parallel to the top surface of the display panel and perpendicular to the first direction, wherein the shielding portion does not cover a side surface of the display panel.

2. The display device of claim 1, wherein the shielding portion contacts a bottom surface of the polarizing plate, and does not cover a side surface of the polarizing plate.

3. The display device of claim 1, wherein the shielding portion partially covers the side surfaces of the adhesive layer.

4. The display device of claim 3, wherein the shielding portion entirely covers the side surfaces of the capping layer.

5. The display device of claim 3, wherein the shielding portion is spaced apart in a thickness direction from the top surface of the display panel.

6. The display device of claim 1, wherein the shielding portion comprises:
a first shielding portion covering one side surfaces of the capping layer and the adhesive layer in the first direction;
a second shielding portion covering the other side surfaces of the capping layer and the adhesive layer in the first direction;
a third shielding portion covering one side surfaces of the capping layer and the adhesive layer in the second direction; and
a fourth shielding portion covering the other side surfaces of the capping layer and the adhesive layer in the second direction,
wherein the display panel includes a pad adjacent to the other side surface of the adhesive layer in the second direction on the top surface of the display panel.

7. The display device of claim 6, wherein an outer surface of each of the first shielding portion, the second shielding portion, and the third shielding portion has a bent shape.

8. The display device of claim 7, wherein each of the first shielding portion, the second shielding portion and the third shielding portion includes a first portion adjacent to the polarizing plate and a second portion adjacent to the display panel, and
an inclination angle of the outer surface of the first portion with respect to the thickness direction is smaller than an inclination angle of the outer surface of the second portion with respect to the thickness direction.

9. The display device of claim 7, wherein the outer surface of the fourth shielding portion has a straight inclined surface.

10. The display device of claim 6, wherein side surfaces of the capping layer and the adhesive layer in the first direction protrude from side surfaces of the display panel in the first direction.

11. The display device of claim 6, wherein the one side surfaces of the capping layer and the adhesive layer in the second direction protrude from one side surface of the display panel in the second direction.

12. The display device of claim 1, wherein the capping layer includes a transparent resin film having a Young's modulus in a range from 0.5 GPa to 1.5 GPa.

13. The display device of claim 1, wherein a thickness of the capping layer is greater than a thickness of the adhesive layer, and the thickness of the capping layer is in a range from 80 μm to 200 μm, and the thickness of the adhesive layer is in a range from 30 μm to 80 μm.

14. A method for manufacturing a display device, comprising:
preparing a capping unit stack comprising a capping liner, a capping layer, and an adhesive layer;
forming a shielding layer covering side surfaces of the capping layer and the adhesive layer on a margin area of the capping liner which is not covered by the capping layer;
attaching the capping unit stack including the shielding layer to a display panel by the adhesive layer;
removing the capping liner;
stacking a polarizing plate on surfaces of the shielding layer and the capping layer from which the capping liner is removed; and
cutting side portions of the polarizing plate and the shielding layer.

15. The method of claim 14, wherein the display panel includes a pad area, wherein cutting the side portions of the polarizing plate and the shielding layer is not performed on a side portion on the display panel adjacent to the pad area.

16. The method of claim 14, wherein the capping unit stack further comprises an adhesive liner stacked on the adhesive layer, and the shielding layer does not contact the adhesive liner.

17. The method of claim 16, wherein the shielding layer is formed to partially cover a side surface of the adhesive layer.

18. The method of claim 16, wherein attaching the capping unit stack to the display panel comprises:
removing the adhesive liner; and
attaching the capping unit stack to a top surface of the display panel by a surface of the adhesive layer from which the adhesive liner is removed.

19. An electronic device, comprising:
a display device;
a memory; and
a processor executing data included in the memory to control an operation of the display device, wherein the display device comprises:
a display panel; and
a capping stack on the display panel, the capping stack comprising:
an adhesive layer attached on the display panel,
a capping layer on the adhesive layer;
a polarizing plate on the capping layer; and
a shielding portion that covers both side surfaces of the adhesive layer and the capping layer in a first direction parallel to a top surface of the display panel and both side surfaces of the adhesive layer and the capping layer in a second direction parallel to the top surface of the display panel and perpendicular to the first direction, wherein the shielding portion does not cover a side surface of the display panel.

20. The electronic device of claim 19, wherein the electronic device includes virtual reality or augmented reality glasses, a smartphone, a tablet personal computer, a laptop, a television, a desk monitor, smart glasses, a head-mounted display, a smart watch, or a vehicle display.
